(19) United States
(12) Patent Application Publication
(10) Pub. No.: US 2015/0349113 A1
(43) Pub. Date: Dec. 3, 2015

(54) SEMICONDUCTOR DEVICE

(71) Applicant: KABUSHIKI KAISHA TOSHIBA, Tokyo (JP)

(72) Inventors: Shunsuke KATOH, Komatsu Ishikawa (JP); Yusuke KAWAGUCHI, Miura Kanagawa (JP); Tetsuro NOZU, Ota Tokyo (JP)

(21) Appl. No.: 14/634,387

(22) Filed: Feb. 27, 2015

(30) Foreign Application Priority Data
May 28, 2014 (JP) 2014-110571

(51) Int. Cl. H01L 29/78; H01L 29/423; H01L 29/08

(52) U.S. Cl. CPC H01L 29/7813; H01L 29/0865; H01L 29/0882; H01L 29/4236

(57) ABSTRACT

According to one embodiment, a semiconductor device, includes a first semiconductor layer of a first conductivity, a second semiconductor layer of a second conductivity type, and a third semiconductor layer of the first conductivity. A first plurality of source elements are spaced from each other and a first gate electrode extends continuously between the source elements. A source electrode is electrically connected to the source elements, and a drain electrode is on the first semiconductor layer such that the first semiconductor layer is between the second semiconductor layer and the drain electrode. By employing this structure, an inactive region decreases, and an active area ratio increases. Thereby, a breakdown voltage can be maintained while an on-resistance can be reduced.

### CROSS-REFERENCE TO RELATED APPLICATION

This application is based upon and claims the benefit of priority from Japanese Patent Application No. 2014-110571, filed May 28, 2014, the entire contents of which are incorporated herein by reference.

### FIELD

Embodiments described herein relate generally to semiconductor devices.

### BACKGROUND

In recent years, the demand for power MOSFET devices has increased rapidly, e.g., in applications such as the switching power supply for mobile communication devices like a notebook PC for which conserving electrical power is highly demanded, while still providing the switching power supply for high current and high voltage applications. To be used in the power management circuit of a mobile communication device, and in the safety circuit of a lithium-ion battery, the power MOSFET needs to be designed to achieve low driving voltage and low on-resistance that enable the direct drive of the switch at the battery voltage, and the reduction of the gate capacitance for curbing the switching loss.

As the technology to realize low on-resistance, a field plate (FP) structure in which a source electrode is embedded in the trench bottom section (without providing an oxide film) may be conceived. However, the FP structure has a problem in that the capacitance between the source and the gate is large, because the source electrode and the gate electrode in the trench are close to each other. This problem is reduced by using a double trench structure that separately provides a trench (source trench) in which the source-potential field plate is embedded, and a trench (gate trench) in which the gate electrode is embedded. However, the double trench structure has a low channel density, and therefore is inferior in on-resistance, as compared to the FP structures.

### DESCRIPTION OF THE DRAWINGS

FIG. 1 is a plan view of a semiconductor device according to a first embodiment.

FIG. 2 is an A-A′ cross-sectional view in FIG. 1.

FIG. 3 is a plan view of a semiconductor device of a double trench structure of a comparative example.

FIG. 4 is a cross-sectional view taken along line B-B′ in FIG. 3.

FIG. 5 illustrates a double trench structure according to a second embodiment.

### DETAILED DESCRIPTION

As described above, the single-trench FP structure has a difficulty in that the capacitance between the source and the gate is large. On the other hand, the double trench structure has the problem of high on-resistance. Embodiments described below provide a semiconductor device with reduced capacitance between the source and the gate, and reduced on-resistance (drift resistance or channel resistance).

According to an embodiment, a semiconductor device, comprises a first semiconductor layer of a first conductivity type, a second semiconductor layer of a second conductivity type on the first semiconductor layer, and a third semiconductor layer of the first conductivity type on the second semiconductor layer. The second semiconductor layer is between the first and third semiconductor layers in a first direction. A first plurality of source trench electrodes (source elements) are each extending along the first direction from the third semiconductor layer into the second semiconductor layer and are spaced from each other along a second direction perpendicular to the first direction. A first gate electrode is extending along the first direction from the third semiconductor layer into the second semiconductor layer and is spaced from the first plurality of source trench electrodes (source elements) in a third direction perpendicular to the first and second directions. The first gate electrode extends continuously (e.g., in a stripe pattern) along the second direction parallel to first plurality of source trench electrodes (source elements). A source electrode is electrically connected to the first plurality of source trench electrodes (source elements). A drain electrode is disposed on the first semiconductor layer such that the first semiconductor layer is between the second semiconductor layer and the drain electrode in the first direction.

In general, according to one embodiment, a semiconductor device includes: a semiconductor substrate of a first conductivity type; a first semiconductor layer of the first conductivity type, formed on the substrate; a second semiconductor layer of a second conductivity type, formed on the first semiconductor layer; a third semiconductor layer of the first conductivity type, formed on the second semiconductor layer; a first trench penetrating the second and third semiconductor layers in a perpendicular direction to a surface of the substrate; a second trench penetrating the second and third semiconductor layers in the perpendicular direction to the surface of the substrate, the second trench being separated from the first trench; a third trench penetrating the second and third semiconductor layers in the perpendicular direction to the surface of the substrate, the third trench being separated from the second trench; a first groove penetrating the second and third semiconductor layers in the perpendicular direction to the surface of the substrate, the first groove being provided in parallel with a direction connecting the first, second and third trenches in a plan view; a first, second and third insulating film formed in the first, second and third trenches, respectively; a first, second and third conductive section formed in the first, second and third trenches, and inside the first, second and third insulating films, respectively; a source electrically connected to the first, second and third conductive sections, and formed on the third semiconductor layer; a fourth insulating film formed in the first groove; a gate formed inside the fourth insulating film; and a drain provided on a back surface side of the substrate.

The semiconductor substrate of the first conductivity type may be a substrate having at least a part of the substrate of the first conductivity type, that is, for example, an appropriately doped portion of the substrate may be formed in or grown on the substrate. Also, the semiconductor substrate of the first conductivity type may be formed integrally with the first semiconductor layer. These semiconductor layers are typically formed by epitaxial growth, but not limited to this. Also, the terms such as parallel and perpendicular are met if the actual product includes a part that substantially meets the term, and allowing for manufacturing tolerances and normal process variations and the like in the production process. Also, a groove has an elongated shape (stripe shape) at least partially in the plan view, as compared to the trench. The trench is not limited to shapes such as a circle and a square in the plan view, but may be any shape.

Also, the above semiconductor device further includes a fourth trench penetrating the second and third semiconductor layers in the perpendicular direction to the surface of the substrate, and a fifth trench penetrating the second and third semiconductor layers in the perpendicular direction to the surface of the substrate, the fifth trench being separated from the fourth trench, wherein a direction connecting the fourth trench and fifth trench in the plan view is in parallel with the first groove, and the first groove is formed between the first, second and third trenches and the fourth and fifth trenches.

Also, in the above semiconductor device, the fourth trench is formed on a perpendicular bisector of the first trench and the second trench in the plan view, and the fifth trench is formed on a perpendicular bisector of the second trench and the third trench in the plan view.

The semiconductor device is satisfactory if a part of the fifth trench is on the perpendicular bisector, and the semiconductor device is not limited to the case where the center of the fifth trench is on the perpendicular bisector of the center of the second trench and the center of the third trench in the plan view.

Also, the electrical connection may be direct or indirect electrical connection.

Also, the above semiconductor device further includes a plurality of sixth trenches located in a dotted pattern separated from each other in the plan view, the sixth trenches penetrating the second and third semiconductor layers in the perpendicular direction to the surface of the substrate, and including an insulating film in the sixth trenches, and a source inside the insulating film, and a plurality of second grooves formed in an striped pattern separated from each other in the plan view, the second grooves penetrating the second and third semiconductor layers in the perpendicular direction to the surface of the substrate, and including an insulating film in the second grooves, and a gate inside the insulating film, wherein a first direction connecting the sixth trenches located between the adjacent second grooves in the plan view is in parallel with the second grooves.

It is desirable that the gate trenches formed in the striped pattern (barred pattern) have a constant pitch, but are not limited to this pattern. Also, the source trenches arranged in the dotted pattern do not necessarily have to be positioned at regularly arrayed lattice points but may be positioned in any arrangement. Also, all source trenches are not necessarily formed and separated in the dotted pattern, but a part (for example, four) of the source trenches may be formed in a separated manner from one another.

Also, in the above semiconductor device, the sixth trenches located between one second groove and an adjacent second groove are formed at different positions in the first direction from the sixth trenches located between the one second groove and an oppositely adjacent second groove, in the plan view. For example, two sixth trenches straddling the groove are formed at positions away from each other in the first direction.

Also, the source electrode in the source trench, and the source electrode formed on the substrate surface may be in direct contact with each other or integral. Also, the source trench may be formed deeper than the gate trench.

Also, In general, according to one embodiment, a semiconductor device includes a semiconductor substrate of a first conductivity type; a fourth semiconductor layer of the first conductivity type, formed on the substrate; a fifth semiconductor layer of the first conductivity type, formed on the first semiconductor layer; a seventh trench penetrating the fifth semiconductor layer in a perpendicular direction to a surface of the substrate; an eighth trench penetrating the fifth semiconductor layer in the perpendicular direction to the surface of the substrate, the eighth trench being separated from the seventh trench; a ninth trench penetrating the fifth semiconductor layer in the perpendicular direction to the surface of the substrate, the ninth trench being separated from the eighth trench; a fourth groove penetrating the fifth semiconductor layer in the perpendicular direction to the surface of the substrate, the fourth groove being provided in parallel with a direction connecting the seventh, eighth and ninth trenches in a plan view; a fourth, fifth and sixth insulating film formed in the seventh, eighth and ninth trenches, respectively; a fourth, fifth and sixth conductive section formed in the seventh, eighth and ninth trenches, and inside the fourth, fifth and sixth insulating films, respectively; a source electrically connected to the fourth, fifth and sixth conductive sections, and formed on the fifth semiconductor layer; a seventh insulating film formed in the fourth groove; a gate formed in the fourth groove, and inside the seventh insulating film; and a drain provided on a back surface side of the substrate. In the device, a dopant concentration of the fifth semiconductor layer is higher than a dopant concentration of the fourth semiconductor layer, and regions between the seventh, eighth, and ninth trenches and the fourth groove in the fourth semiconductor layer are depleted, respectively.

According to this structure, by providing the depletion region, the region of the second conductivity type need not be provided as the base. However, it is desirable that the gap between the trench and the gate is narrow (for example, equal to or less than 100 nm) for the purpose of depletion region formation.

In the following, a semiconductor device according to an embodiment will be described with reference to the drawings. In the following description, the first conductivity type is n type, and the second conductivity type is p type, but they may be reversed. Also, n+ means a higher dopant concentration than n, and n means a higher dopant concentration than n−. The same notation convention is applicable to p type concentrations.

### First Embodiment

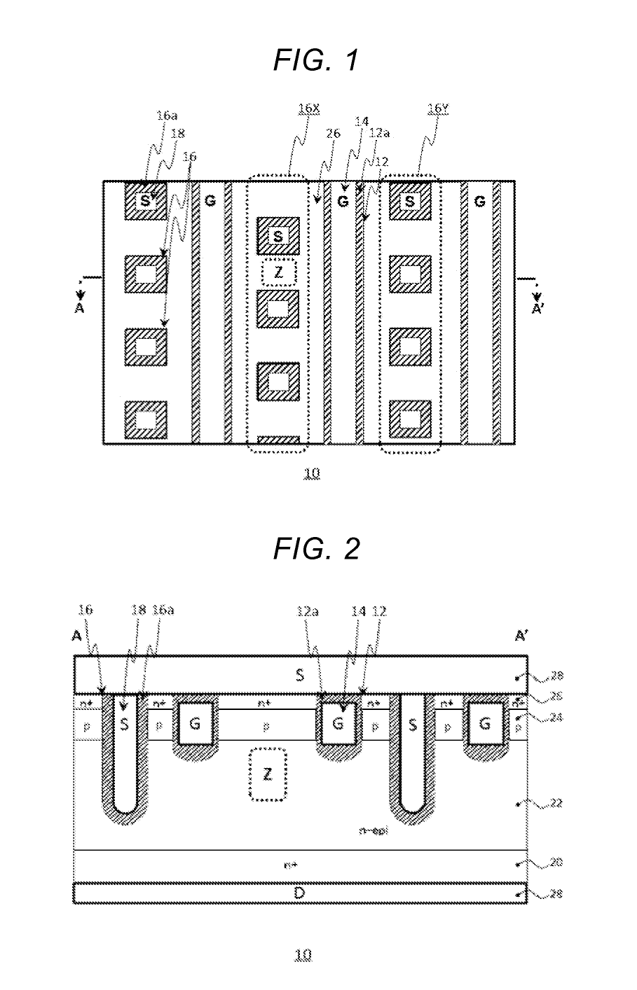

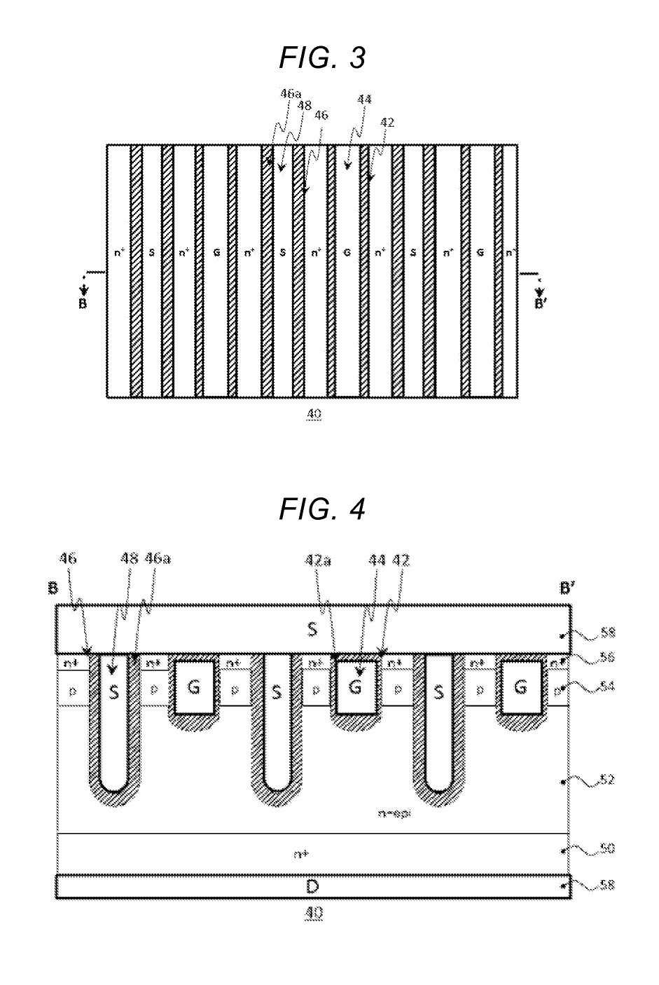

FIG. 1 is a plan view of a semiconductor device 10 according to the present embodiment, and FIG. 2 is a schematic view of A-A′ cross-section of FIG. 1. For the purpose of explanation, a source electrode 28 covering the substrate surface and a part of a gate insulating film 12a are omitted from the depiction in FIG. 1. FIG. 3 is a plan view of a semiconductor device 40 of a double trench type device of a comparative example, and FIG. 4 is a schematic view of B-B′ cross-section in FIG. 3.

As illustrated in FIG. 1 and FIG. 2, the semiconductor device 10 includes a plurality of gate trenches 12, and a plurality of source trenches 16. The gate trenches 12 extend linearly (in the vertical (up-down page) direction with respect to the sheet of FIG. 1) in the plan view. The gate trenches 12 are in parallel with each another, and are formed with constant spacing intervals (for example, 3 μm pitch). As illustrated in FIG. 1, the source trenches 16 are formed in substantially a rectangular shape in the plan view, (which in actual products may have rounded corners). The source trenches 16 are formed in the regions between the adjacent gate trenches 12. The source trenches are also arranged in the vertical direction (up-down page direction) within the regions between adjacent gate trenches at constant spacing intervals (for example, 3 μm pitch). A plurality of source trench groups 16X formed between the adjacent gate trenches 12, and a plurality of source trench group 16Y adjacent thereto are formed at positions a half pitch away from each other in the vertical direction on the sheet. In other words, the respective center of each of the source trenches 16 belonging to the source trench group 16Y is located on a perpendicular bisector of the respective centers of the source trenches 16 of the source trench groups 16X. As a result, in the plan view, the source trenches 16 are in a scattered dotted pattern, while the gate trenches 12 are formed in a striped pattern.

As illustrated in FIG. 2, the gate insulating film 12a is formed on the inner surface of the gate trench 12, and the gate electrode 14 made of polysilicon is formed in the insulating film 12a, for example. The gate electrodes 14 are electrically connected to each other (not illustrated in the drawings). Also, the insulating film 16a is coated on the inner surface (the bottom section and the side surface) of the source trench 16, and in addition a source electrode (source element) 18 is formed inside the insulating film. 16a. For this reason, the source electrode 18 is insulated except for contact/connection to a source electrode 28.

Further, as illustrated in FIG. 2, a drift layer 22 of n− type, which is made of silicon for example, is formed by epitaxial growth on an n+ type semiconductor substrate 20 that serves as the drain region, and further a base layer 24 of p type is formed on the drift layer 22, and further an n+ layer 26 that serves as the source region is formed on the base layer 24. Then, the source electrode 28 is provided to cover the n+ layer 26 that serves as the source region, the top surfaces of the gate insulating films 12a (i.e., the surface of the front surface of the semiconductor substrate 20), and the top surfaces of the source electrodes (source elements) 18 and the source insulating films 16a. This source electrode 28 is in contact with, and electrically directly connected to (short circuited), the top surfaces of the source electrodes 18 and the source regions 26. For this reason, the capacitance is reduced.

Also, a drain electrode 28 is formed on the back surface of the semiconductor substrate 20. The dopant concentration of the semiconductor substrate 20 is set within a range from about 5.0e19 to about 1.0e20 (cm⁻³) for example, and the dopant concentration of the drift layer 22 is set at about 1.75e17 (cm⁻³) as one example, and the dopant concentration of the source region is set at about 1.0e19 (cm⁻³) for example.

The deepest section of the gate trench 12 and the deepest section of the source trench 16 are each positioned in the drift layer 22. That is, the respective trenches extend into the drift layer 22 from the upper surface of the substrate 20 (or source layer 26 formed thereon). To raise the breakdown voltage, it is desirable that the source trench 16 be deeper (extend further into the drift layer 22) than the gate trench 12, and that the gate trench 12 have a depth of about 1 μm, and the source trench 16 have a depth of 4 μm (with reference to the boundary between the source electrode 28 and the electrode 18 or boundary between source region 26 and source electrode 28). Also, in general, the film thickness of the insulating film 16a of the source trench should be thicker than the film thickness of the gate insulating film 12a of the gate trench 12, and in a particular embodiment the insulating film 16a has a thickness of 300 nm, and the gate insulating film 12a has a thickness of 50 nm. The insulating film 16a and the gate insulating film 12a may be, for example, oxide films.

The double trench semiconductor device 40 of a comparative example is illustrated in FIG. 3 and FIG. 4. As illustrated in FIG. 3, this semiconductor device 40 includes gate trenches 42, gate insulating films 42a, gate electrodes 44, source trenches 46, insulating films 46a, and source electrodes 48. Also, as illustrated in FIG. 4 illustrating the B-B′ cross-section in FIG. 3, the semiconductor device also includes a drain electrode 58 a semiconductor substrate 50, a drift layer 52, a base layer 54, a source region 56, and source electrode 58.

The source trench 46 of the semiconductor device 40 in a comparative example and the source electrode 46 formed inside the source trench 46 and are different from the semiconductor device 10 in that the source trenches 46 are formed in the striped pattern in the same way as the gate trenches 42 and the gate electrodes 44 rather than an arrangement of dots or spaced portions along the vertical (top-bottom page of FIG. 3) direction between the gate trenches 42.

In the case of the semiconductor device 10, since the bottom surface of the source electrode 28 and the top surface of the source electrode 18 are in direct contact with each other, and the source trenches 16 (and the source electrode 18 within source trenches 16) are arranged in the dotted pattern in the plan view, the drift region portion between the source trenches 16 (for example, the region Z in FIG. 1 and FIG. 2) may be used as the active region. As a result, the active area ratio may be increased 1.5 times or more from 48% active area ratio in a comparative example to 74% of the depicted embodiment in FIG. 1.

Specifically, if the breakdown voltage is increased (for example, to 100 V), the influence of the drift resistance becomes larger than the channel resistance among the on-resistance, and therefore the advantage of the structure of the present embodiment is utilized more. Further, since the source trench groups 16X and the adjacent source trench group 16Y are positioned a half pitch away from each other in the vertical direction on the sheet in FIG. 1, the breakdown voltage is raised with the same structure, as compared to when the source trenches centers are aligned with each other in the left-right page direction of FIG. 1. Also, setting the film thickness of the source oxide film 16a thicker than the gate oxide film 12a, and forming the source trenches 16 deeper than the gate trenches 12 improves (increases) the breakdown voltage. When targeting a breakdown voltage of about 30 V, the film thickness of the source oxide film may be a thickness of about 100 nm, for example.

Also, the shape of the source trench is not necessarily rectangular in the plan view, but may be rounded or circular for example. By providing a plurality of the source trenches in a separated manner between the adjacent gates of the striped pattern, the region between the source trenches may be used as the active region. However, for the purpose of securing the active region, it is desired that the width of the source trench in the vertical direction (up-down page direction of FIG. 1), and the width in the lateral direction (left-right page direction of FIG. 1) be about from 5:1 to about 1:5 in the plan view (the boundary surface between the source electrode and the embedded source electrode). The cross-sectional shape of the source trench may be changed as appropriate through the depth of the, and may be in a tapered shape with a thin tip (deepest portion of the trench), for example. The film thickness is not necessarily constant either.

Also, in the semiconductor device according to the present embodiment, the source trench groups 16X and 16Y are positioned a half pitch away from each other, but the effect of making the above active region available is exerted even when the source trench groups 16X and 16Y are not positioned away from each other. Also, as described above, it is more preferred that the bottom surface of the source electrode 28 and the top surface of the source electrode 18 be in direct contact with each other, but a different embedded source electrode structure may be employed and electrical contact between elements may be made indirectly.

The gate trench and the source trench in the semiconductor device 10 need not cover the structure over all region of the device, but may cover only least a part of the region rather than fully covering the entire device.

As described above, in the semiconductor device 10 according to the present embodiment, the volume of the source trench, which is an inactive region, decreases, and the active area ratio per unit area thus increases. Accordingly, the breakdown voltage is maintained, while the on-resistance is reduced.

### Modified Example

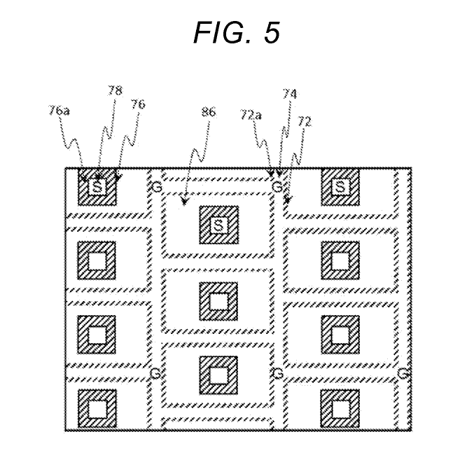

With reference to FIG. 5, a semiconductor device 70, which is a variant example of the first embodiment, will be described. The semiconductor device 70 includes gate trenches 72, gate insulating films 72a, gate electrodes 74, source trenches 76, insulating films 76a, and source electrodes 78. Also, although specific description is omitted, the drain electrode, the semiconductor substrate, the drift layer, the base layer, the source region, and the source electrode are included likewise as in the semiconductor device 10. That is, the gate trenches 72 are formed in sort of a mesh pattern in such a manner to connect with each other between the source trenches formed in the dotted pattern. In other words, the gate trench 72 is a structure of combination of a plurality of linear groove sections extending in the first direction (the vertical direction (top-bottom page) on the sheet of FIG. 5), and a plurality of linear groove sections (connectors) extending in the second direction (the lateral direction (left-right page) on the sheet of FIG. 5) perpendicular to the first direction, in the plan view. Then, the gates provided in the gate trenches 72 are in electrical contact with each other (short circuited). Here, the length of the groove section extending in the lateral direction on the sheet in the plan view (in the lateral direction on the sheet) is equal to the pitch of the linear groove section in the vertical direction on the sheet. In other words, the adjacent two groove sections extending in the vertical direction on the sheet are at both ends. Further, in the same way as the first embodiment, the source trenches are positioned a half pitch away from each other in the vertical direction on the sheet, and along with this the groove sections of the gate trenches extending in the lateral direction on the sheet are formed at positions a half pitch away from each other. The depth of the gate trench 72 is approximately constant, but is not limited to this. Then, the source trenches 76 are each formed in the regions 86 surrounded by the gate trenches 72 in the plan view. When employing a structure like this, the channel region may be increased about 75%, as compared to the comparative example.

In the present variant example, a single source trench 76 is formed in the region surrounded within an enclosed (rectangular) section (region 86) formed by the gate trench 72, but this is not a limitation, and a plurality of source trenches 76 may be provided within the enclosed section(s) (region(s) 86) formed by the gate trench 72. Also, various alterations and modifications described in conjunction with the first embodiment may be further employed in the modified example. According to the semiconductor device 70 like this, the channel region is increased, and therefore the on-resistance is reduced.

Although the semiconductor devices using the silicon substrate are illustrated in the above embodiments (including the variant example), these embodiments and examples may be applied to a semiconductor device using a SiC substrate or other semiconductor substrates.

Also, in the above embodiment (including the variant example), the n type drift layer 22 is formed on the n type semiconductor substrate 20 by the epitaxial growth, and in addition the p type base layer 24 and the n type source region 26 are formed by ion implantation or the like, but this is not a limitation. For example, if the interval between the gate trenches 12 and the source trenches 16 is set at 100 nm or less, and the difference between the work function of the material (for example, silicon) of the drift layer and the work function of the gate electrode is set at the threshold voltage of the MOSFET or more, the region between the gate trenches 12 and the source trenches 16 is completely depleted or partially depleted. Thereby, the n+ type source region may be provided directly on the n− type layer, without providing the p type layer therebetween. If the p type base layer is located between the trenches, the concentration of the p type base layer should be increased to obtain the necessary threshold voltage, thereby preventing the reduction of the channel resistance in proportion to the downsizing of the interval of the trenches. If the p type base layer is not required to be formed in the channel section, the channel resistance may be reduced in proportion to the shortening of interval of the trenches. Also, with regard to the drift resistance, by employing the source trenches arranged in the dotted pattern, the reduction of the drift resistance is achieved as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer of a first conductivity type;
a second semiconductor layer of a second conductivity type on the first semiconductor layer;
a third semiconductor layer of the first conductivity type on the second semiconductor layer, the second semiconductor layer being between the first and third semiconductor layers in a first direction;
a first plurality of source elements each extending along the first direction from the third semiconductor layer into the second semiconductor layer and spaced from each other along a second direction perpendicular to the first direction;
a first gate electrode extending along the first direction from the third semiconductor layer into the second semiconductor layer and spaced from the first plurality of source elements in a third direction perpendicular to the first and second directions, the first gate electrode extending continuously along the second direction parallel to the first plurality of source elements;
a source electrode electrically connected to first plurality of source elements; and
a drain electrode on the first semiconductor layer such that the first semiconductor layer is between the second semiconductor layer and the drain electrode in the first direction.

2. The semiconductor device according to claim 1, further comprising:
a second plurality of source elements each extending along the first direction from the third semiconductor layer into the second semiconductor layer and spaced from each other along the second direction perpendicular, the second plurality of source elements spaced in the third direction from the first plurality of source elements and the first gate electrode such that the first gate electrode is between the first plurality of source elements and the second plurality of source elements.

3. The semiconductor device according to claim 2, wherein
spacing between source elements in the first plurality of source elements is at a first pitch along the second direction, and
spacing between source elements in the second plurality of source elements is at the first pitch along the second direction.

4. The semiconductor device according to claim 3, wherein the second plurality of source elements is offset in the second direction by one-half of the first pitch from the first plurality of source elements.

5. The semiconductor device according to claim 4, wherein the first gate electrode includes a plurality of portions which extend along the third direction such that a portion of the first gate electrode is between each adjacent pair of source elements in the first plurality of source elements and between each adjacent pair of source elements in the second plurality of source elements.

6. The semiconductor device according to claim 2, wherein the first gate electrode includes a plurality of portions which extend along the third direction such that a portion of the first gate electrode is between each adjacent pair of source elements in the first plurality of source elements and between each adjacent pair of source elements in the second plurality of source elements.

7. The semiconductor device according to claim 1, further comprising:
a gate insulating layer between the first gate electrode and the first, second, and third semiconductor layers; and
a source element insulating layer between each source element in the first plurality of source elements and the first, second, and third semiconductor layers.

8. The semiconductor device according to claim 1, wherein the source electrode is directly contacting each source element in the first plurality of source elements.

9. The semiconductor device according to claim 1, wherein the first plurality of source elements extends along the first direction into the first semiconductor layer for a first distance and the first gate electrode extends along the first direction into the first semiconductor layer for a second distance that is less than the first distance.

10. The semiconductor device according to claim 1, wherein the first conductivity type is n-type and the second conductivity type is p-type.

11. The semiconductor device according to claim 1, further comprising:
a second plurality of source elements each extending along the first direction from the third semiconductor layer into the second semiconductor layer and spaced from each other along the second direction perpendicular, the second plurality of source elements spaced in the third direction from the first plurality of source elements and the first gate electrode such that the first gate electrode is between the first plurality of source elements and the second plurality of source elements; and
a second gate electrode extending along the first direction from the third semiconductor layer into the second semiconductor layer and spaced from the first gate electrode and the second plurality of source elements in the third direction, the second gate electrode extending continuously along the second direction parallel to second plurality of source elements.

12. The semiconductor device according to claim 11, wherein
spacing between elements in the first plurality of source elements is at a first pitch along the second direction,
spacing between source elements in the second plurality of source elements along the second direction is at the first pitch, and
the second plurality of source elements is offset by one-half of the first pitch in the second direction from the first plurality of source elements.

13. The semiconductor device according to claim 12, wherein
the first gate electrode includes:
a plurality of first portions which extend along the third direction such that a first portion is between each adjacent pair of source elements in the first plurality of source elements, and
a plurality of second portions which extend along the third direction such that a second portion is between each adjacent pair of source elements in the second plurality of source elements, and
the first and second gate electrodes are electrically connected by the second portions.

14. The semiconductor device according to claim 11, wherein
the first gate electrode includes:
a plurality of first portions which extend along the third direction such that a first portion is between each adjacent pair of source elements in the first plurality of source elements, and
a plurality of second portions which extend along the third direction such that a second portion is between each adjacent pair of source elements in the second plurality of source elements, and
the first and second gate electrodes are electrically connected by the second portions.

15. A semiconductor device, comprising:
a semiconductor substrate of a first conductivity type;
a first semiconductor layer of the first conductivity type on the semiconductor substrate;
a second semiconductor layer of a second conductivity type on the first semiconductor layer;
a third semiconductor layer of the first conductivity type on the second semiconductor layer;
a first trench penetrating the second and third semiconductor layers in a perpendicular direction to a surface of the semiconductor substrate;
a second trench penetrating the second and third semiconductor layers in the perpendicular direction to the surface of the semiconductor substrate, the second trench being separated from the first trench;
a third trench penetrating the second and third semiconductor layers in the perpendicular direction to the surface of the substrate, the third trench being separated from the second trench;
a first groove penetrating the second and third semiconductor layers in the perpendicular direction to the surface of the substrate, the first groove being provided in parallel with a direction connecting the first, second and third trenches in a plan view;
a first, second, and third insulating film formed in the first, second and third trenches, respectively;
a first, second and third conductive section formed in the first, second, and third trenches, and inside the first, second and third insulating films, respectively;
a source electrode electrically connected to the first, second, and third conductive sections, and on the third semiconductor layer;
a fourth insulating film formed in the first groove;
a gate electrode in the fourth insulating film; and
a drain electrode provided on a back surface side of the substrate.

16. The semiconductor device according to claim 15, further comprising:
a fourth trench penetrating the second and third semiconductor layers in the perpendicular direction to the surface of the substrate; and
a fifth trench penetrating the second and third semiconductor layers in the perpendicular direction to the surface of the substrate, the fifth trench being separated from the fourth trench, wherein
a direction connecting the fourth trench and the fifth trench in the plan view is parallel with the first groove, and
the first groove is formed between the first, second and third trenches, and the fourth and fifth trenches.

17. A semiconductor device, comprising:
a plurality of source elements arranged in a dotted pattern such that the source elements are separated from each other in a first plane of a first semiconductor layer of a first conductivity type, the source elements penetrating, in a first direction orthogonal to the first plane, a second semiconductor layer of a second conductivity type disposed on the first semiconductor and a third semiconductor layer of the first conductivity type disposed on the second semiconductor layer;
an insulating film adjacent to each source element and between each source element and the first, second, and third semiconductor layers;
a gate electrode in a plurality of grooves formed in an striped pattern spaced from each other in a second direction parallel to the first plane and extending along a third direction that is parallel to the first plane and perpendicular to the second direction, the grooves penetrating the second and third semiconductor layers in the first direction; and
a gate insulating film between the gate electrode and the first, second, and third semiconductor layers, wherein
the source elements are between the plurality of grooves.

18. The semiconductor device according to claim 17, wherein the plurality of source elements extend along the first direction into the first semiconductor layer for a first distance and the plurality of grooves extends along the first direction into the first semiconductor layer for a second distance that is less than the first distance.

19. The semiconductor device according to claim 17, wherein the dotted pattern of the plurality of source elements has rows and columns and each column of the dotted pattern is between a respective pair of adjacent grooves and each column of the dotted pattern is disposed with one-half pitch offset from each adjacent column of the dotted pattern.

20. The semiconductor device according to claim 17, further comprising:
a plurality of connector grooves extending between adjacent grooves of the plurality of grooves and electrically connecting portions of the gate electrode in adjacent grooves, the connector grooves passing between adjacent source elements in the dotted pattern.
